(19) United States
(12) Patent Application Publication
(10) Pub. No.: US 2026/0261101 A1
(43) Pub. Date: Sep. 3, 2026

(54) Arc Fault (AFCI) and Ground Fault (GFCI) Detection and Interruption Implemented in a Branch Module for a Modular Electrical Panel

(71) Applicant: Span.IO, Inc., San Francisco, CA (US)

(72) Inventors: Birger Pahl, Milwaukee, WI (US); Arnaldo Mario Arancibia Moreno, San Mateo, CA (US); Michael Motola-Barnes, San Francisco, CA (US); Ian Casimir Dimen, Berkeley, CA (US); Hans von Clemm, San Francisco, CA (US)

(21) Appl. No.: 19/546,282

(22) Filed: Feb. 20, 2026

Related U.S. Application Data
(60) Provisional application No. 63/762,537, filed on Feb. 24, 2025.

(51) Int. Cl. H02B 1/42; G01R 31/14; G01R 31/52; H02B 1/20; H02H 7/22

(52) U.S. Cl. CPC H02B 1/42; G01R 31/14; G01R 31/52; H02B 1/20; H02H 7/222

(57) ABSTRACT

An electrical includes a chassis with a bus structure that receives electrical power and a predefined attachment points for installation of field-replaceable control modules. A field-replaceable branch module is installed at the attachment points with electrical connection to the bus structure. The branch module distributes electrical power from the bus structure to multiple branch circuits of the microgrid and provides AFCI and/or GFCI protection for the branch circuits. A field-replaceable panel control module is installed at one of the attachment points with electrical connection to the bus structure. The panel control module maintains a registry that includes the installed branch module. An intra-panel communications network is used for the panel control module to communicate data and control with the branch module.

### CROSS-REFERENCE TO RELATED APPLICATION(S)

This application claims priority under 35 U.S.C. § 119(e) to U.S. Provisional Patent Application Ser. No. 63/762,537, “Arc Fault (AFCI) and Ground Fault (GFCI) Detection and Interruption Implemented in a Branch Module for a Modular Electrical Panel,” filed Feb. 24, 2025. The subject matter of all of the foregoing is incorporated herein by reference in its entirety.

### BACKGROUND

### 1. Technical Field

This disclosure relates generally to management and control of the distribution of electrical power.

### 2. Description of Related Art

Continued electrification will add massive amounts of demand to electrical distribution. Estimates are that net distribution capacity in the U.S. will increase by two to three times to support fully renewable energy sources. The current distribution system and site-level (e.g. building) wiring are not well instrumented and not easily controllable. They are not well suited to implement sophisticated energy management.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIG. 1 is a diagram of a Branch Module that supports 8 branch circuits.

FIGS. 2-6 are diagrams of Branch Modules with different AFCI/GFCI protection.

FIGS. 7A-7C are screenshots of an app illustrating fault indications.

FIG. 8 is a diagram of a Branch Module with decentralized AFCI/GFCI functionality.

FIG. 9 is a diagram of a Branch Module with centralized AFCI/GFCI functionality.

FIG. 10 is an exploded view of an electrical panel with a modular chassis.

FIG. 11 is a block diagram of a modular system for managing electrical power distribution throughout a microgrid at a site.

FIG. 12 is a block diagram of a module from the modular system of FIG. 11.

FIG. 13 is a block diagram of a chassis from the modular system of FIG. 11.

FIG. 14 is a block diagram of an electrical panel, suitable for use with a modular system for managing electrical power distribution.

FIG. 15 is a block diagram of a Branch Module from the electrical panel of FIG. 14.

FIG. 16 is a block diagram of a panel control module from the electrical panel of FIG. 14.

### DETAILED DESCRIPTION OF THE PREFERRED EMBODIMENTS

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

### I. Branch Modules With AFCI and/or GFCI Protection

With increased electrification, there is a need for more sophisticated management and control of electrical power distribution at the site-level, for example for residential homes and commercial properties. The site-level electrical power distribution system is referred to as a microgrid. It would be beneficial if management of the microgrid was integrated into structures and other sites in the same way as heating, plumbing, and lighting. It would also be beneficial if this integration was modular and field-customizable. This would allow installers to retrofit more sophisticated power management to existing structures and to modify those capabilities as the electrical needs grow or change and as more capabilities become available.

In one approach, a system for managing electrical power distribution for the microgrid at a site includes a customizable modular smart panel chassis and a set of chassis-compatible hardware modules. The chassis is designed to hold the hardware modules, which in turn are connected to circuits. The modules are field-installable and field-replaceable. Accordingly, more modules may be added as more circuits are added and/or as more management capabilities become available. The chassis itself may also be field-customizable, for example extendible in size to accommodate more modules. See Sections IV-V for additional information.

One type of module is a Branch Module. The Branch Module is a basic building block of the electrical panel. These control modules are a modularized section of panel for branch circuit breakers with integrated controls and sensing. As described below, a single Branch Module can provide voltage sensing, current sensing, arc fault detection, ground fault detection and load disconnection for up to a certain number of branches (e.g., eight branches in the examples below). The module is mechanically and electrically integrated into the chassis of the electrical panel, such as may be provided by Span. Such a module can provide an integrated AFCI and/or GFCI solution. The AFCI and GFCI circuitry may be embedded in a module that supports multiple branches. The module may have a unique mechanical form factor and sensing capabilities which differentiate from conventional arc fault and ground fault circuit interrupters.

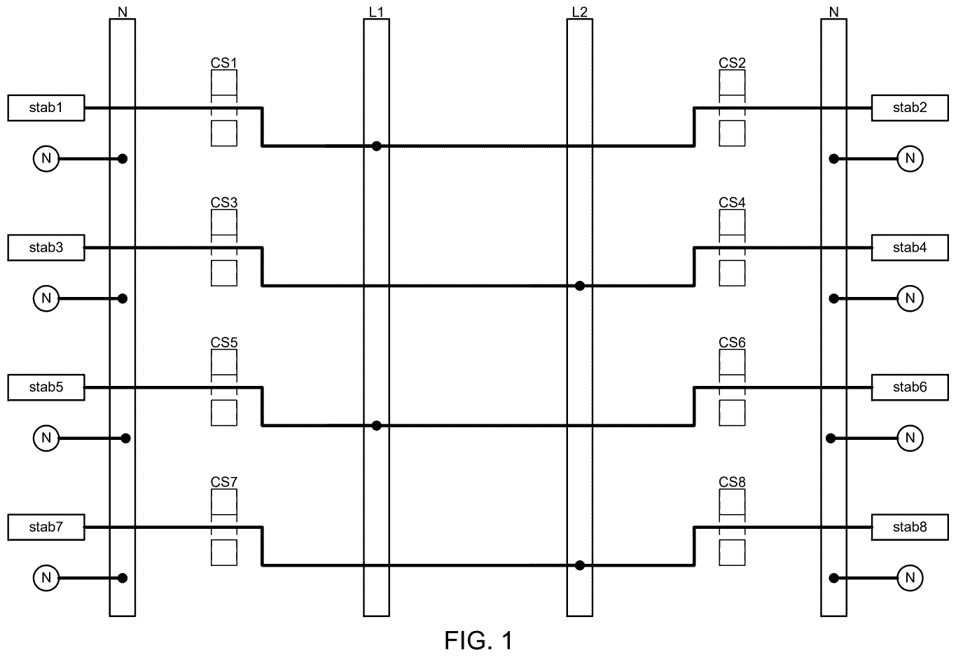

FIG. 1 is a diagram of a Branch Module that supports 8 branch circuits, which are connected to stabs1-8. This 8 circuit module can have any variations and combinations of AFCI and GFCI. The following figures show some of the implementations. In these examples, current sensing can be done by various methods. e.g. current sensing through a shunt resistor, current transformer, HALL effect sensor, inductive sensing, or capacitive sensing—or any combination thereof.

The Branch Module has the bussing and mechanical connection to receive a regular circuit breaker at each of the stabs1-8. The electrical connections to L1 and L2 are made in the module, as shown by the black circles that connect L1 or L2 vertical bars to conductors for the stabs. L1 is connected to stabs1-2 and 5-6, while L2 is connected to stabs3-4 and 7-8. N is neutral. Each branch circuit has a current sensor (the structures labelled CS1-CS8) that senses the current flowing through the branch circuit.

The following figures show examples of how AFCI functionality (structures labeled AF) and GFCI functionality (structures labeled GF) may be added to this implementation of a Branch Module.

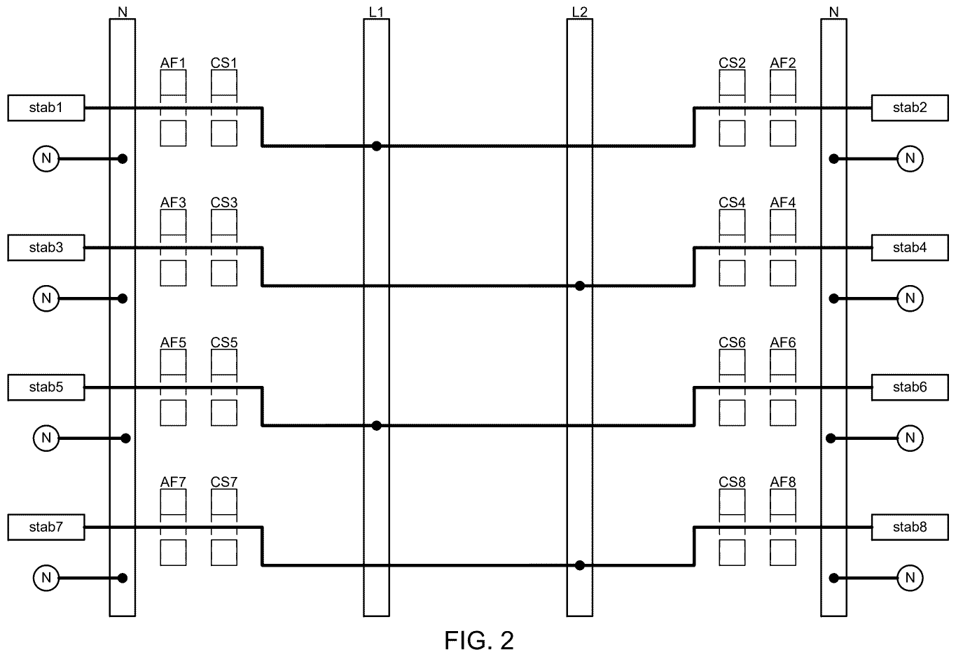

FIG. 2 shows adding AFCI protection (AF1-AF8) for each individual branch, with the following features:
Dedicated electronics per branch
Processing may happen in a central processor for each branch or for multiple branches (8, 4, or 2)
Dedicated current sensing per branch for high frequency
Relay control through existing mechanism
Load neutral connection to existing panel neutral bar

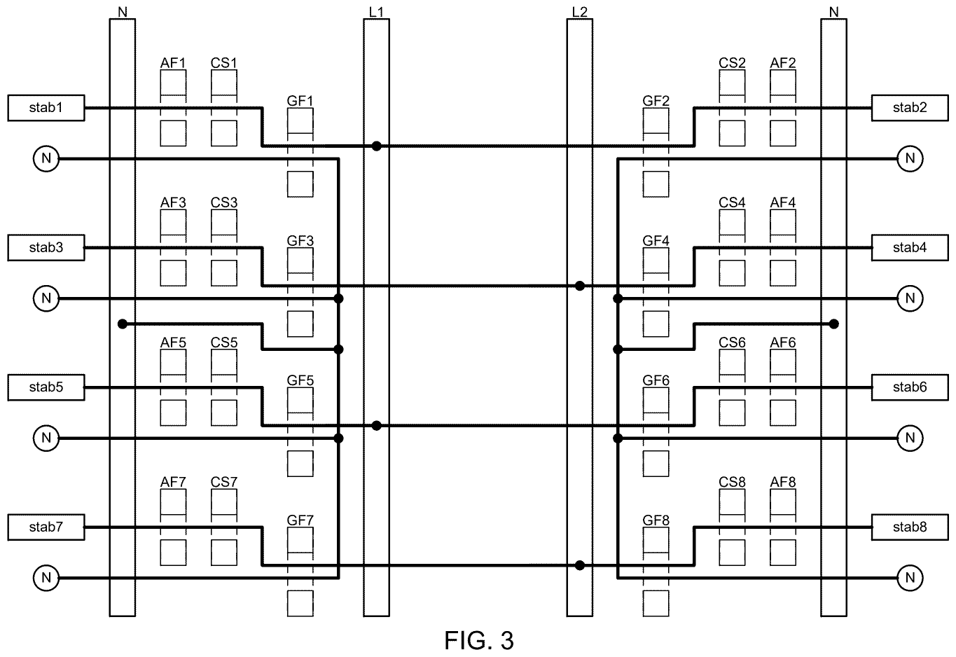

FIG. 3 shows adding AFCI (AF1-AF8) and GFCI (GF1-GF8) for each branch, with the following features:
Dedicated electronics per branch
Processing may happen in a central processor for a single or multiple branches (8, 4, or 2)
Dedicated current sensing per branch for high frequency for each branch
Dedicated CS per branch for GFCI
Load Neutral connection to branch
Neutral connection from Branch Module to neutral bus bar
Relay control through existing mechanism
Support for AFCI for tandem breakers. The branches may be rated to support at least 20 A rated tandem breakers (40 A total). AFCI algorithms can take the rating into account. A single relay will disconnect the branch for both breaker outputs.

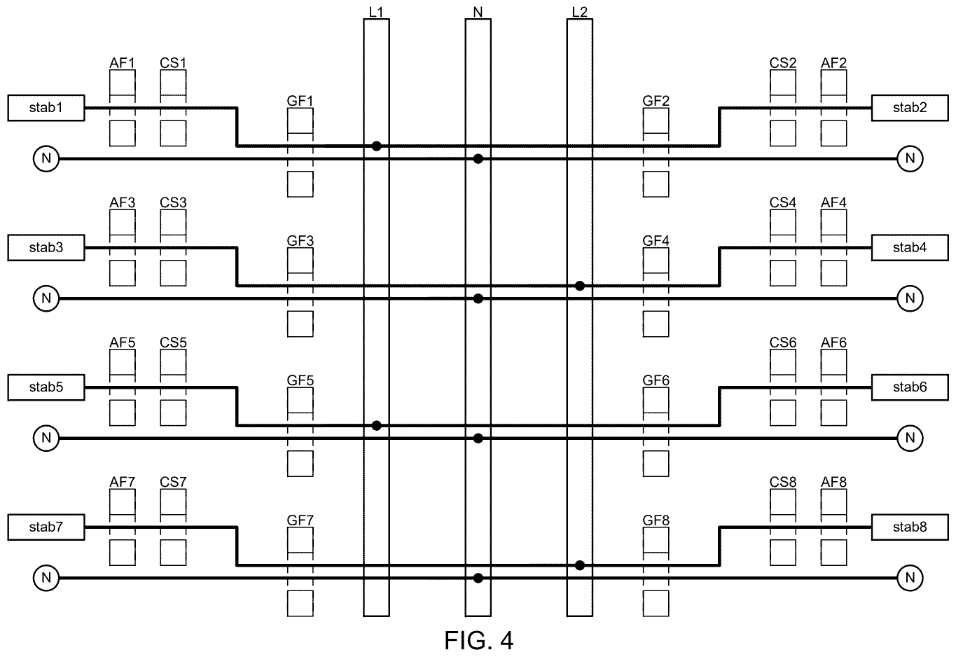

FIG. 4 shows adding AFCI (AF1-AF8) and GFCI (GF1-GF5, GF7) for the branches, with one or more spaces to provide GFCI (e.g., GF68) for 120/240V circuits (dipole breakers), with the following features:
Dedicated electronics per branch
Processing may happen in a central processor for a single or multiple branches (8, 4, or 2)
Dedicated current sensing per branch for high frequency for each branch
Dedicated CS per branch for GFCI
Dedicated CS per 2 branch for GFCI for 240V/120V dipole breakers in one or more locations
Mechanism for both relays that have dipole breakers to open during fault condition
Load Neutral connection to branch
Neutral connection from Branch Module to neutral bus bar
Relay control through existing mechanism

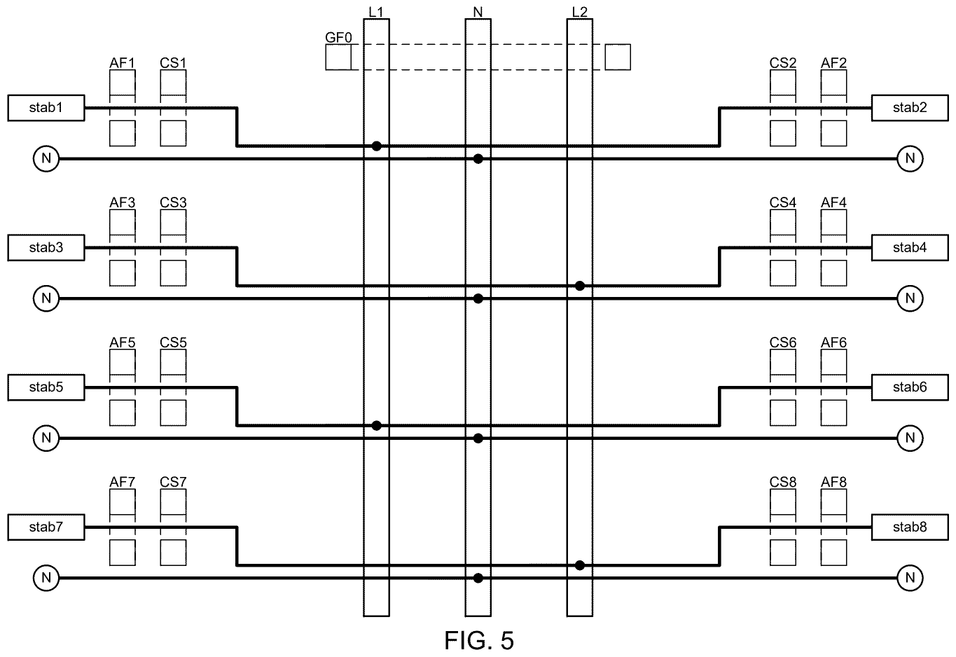

FIG. 5 shows a centralized GFCI (GF0) per module with AFCI (AF1-AF8) per branch, with the following features:
Dedicated electronics per branch
Processing may happen in a central processor for single or multiple branches (8, 4, or 2)
Dedicated current sensing per branch for high frequency, or resistive pickup
One CS per module for GFCI
Load Neutral connection to branch
Neutral connection from Branch Module to neutral bus bar
Relay control through existing mechanism

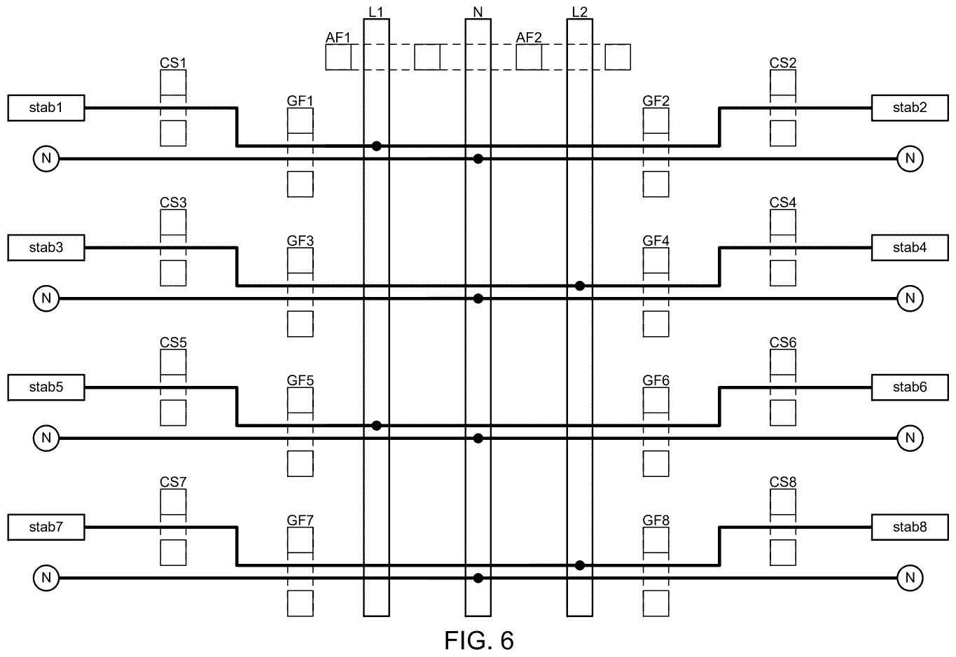

FIG. 6 shows a centralized AFCI (AF1-AF2) with branch GFCI (GF1-GF8), with the following features:
Dedicated electronics per branch
AFCI processing can happen in a central processor for the module separately for L1 and L2
Dedicated current sensing per module for high frequency, or resistive pickup for L1 and L2
One CS per branch for GFCI
Correlation of what branch has the fault by processing the signal of the energy monitoring current sensor of each branch
Load Neutral connection to branch
Neutral connection from Branch Module to neutral bus bar
Relay control through existing mechanism

### II. System and Application Features

Generally GFCIs detect a ground fault for protection at a very low current level of 6 mA. The system can implement several features relying on a variable GFCI current level. For circuits that do not require 6 mA level protection, the system can have that level be adjusted to a higher level like 30 mA or 200 mA to provide equipment level protection or protection for arcing against ground. The system can also provide a warning level at a relatively low ground fault at 3 mA or 4 mA to make the user aware that there is a problem without having to shut down electricity. This would give a warning of an isolation fault that would be diagnosed by an electrician.

The system can provide over-the-air updates (OTA) for new features and for AFCI (according to UL1699). Features could include detection of new faults, new algorithms for fault detection, or avoidance of unwanted fault indications for future loads. The OTA process may be managed by the panel and may be done in a safe manner to ensure the system is not unprotected during the process. This for example can be done by switching the branch(es) off that are being updated during the process. The OTA process can address unwanted false-positives of the algorithm.

The system can also provide automatic lockouts under certain detected conditions. Lockout means that the circuit will be de-energized, e.g. by opening the relay. This could be done at the branch, module, system, or panel level. The system may institute lockout during abnormal voltage, e.g. low voltage, abnormalities during islanded mode. As another example, it may lockout when multiple branch circuits are having a fault.

The system can store a fault history of fault types and frequency, report back to the app or the cloud. The data can be aggregated over multiple panels or over multiple sites. The homeowner can be notified with the app on why a branch circuit tripped and what to do about it. An electrician can read what type of fault happened to speed up finding the root cause. A service arrangement through the cloud connected system can be made where an electrician or company is notified to reach out to the homeowner. The homeowner can provide feedback through the app after a fault occurred to help determine what happened. The fault can be correlated with the energy monitoring information to provide more insight (e.g. the system gets a GF every time the compressor of the fridge starts) and notification of the homeowner in the app.

The panel may provide a user interface (e.g., at least one LED and electrical button) to provide visual indication that a fault trip occurred, what kind of fault occurred, and the state of that branch circuit (energized or non-energized). The same information may be made available through an app. The reset can occur on the button of that branch in the panel or on the app. The app can have a mechanism that requires proximity to the panel before being able to reset the fault.

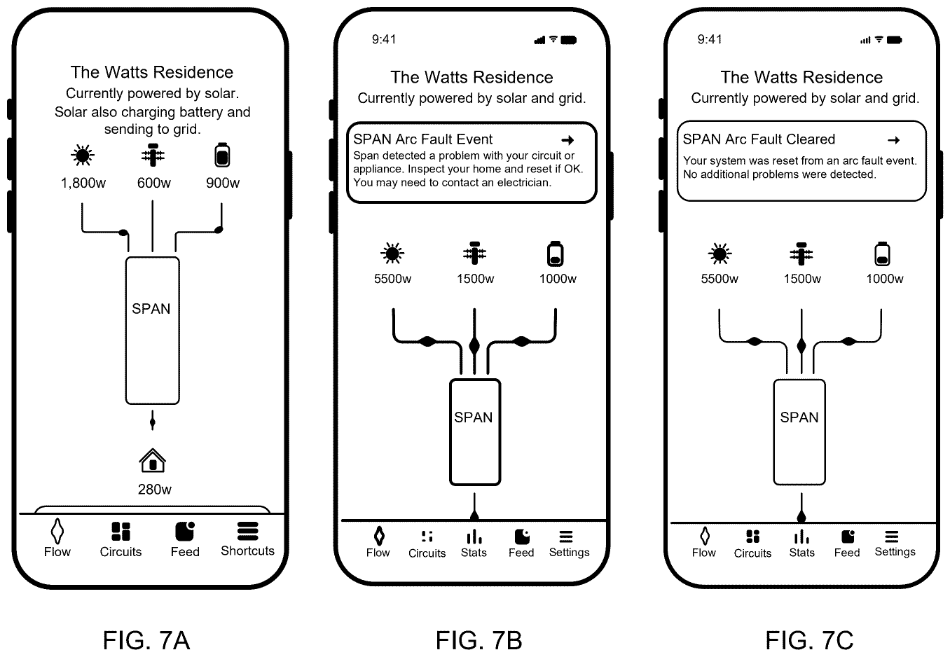

FIGS. 7A-7C show an example of fault indication in the app. FIG. 7A shows a normal state, FIG. 7B shows a faulted state, and FIG. 7C shows a reset state:

### III. Architectural Representations

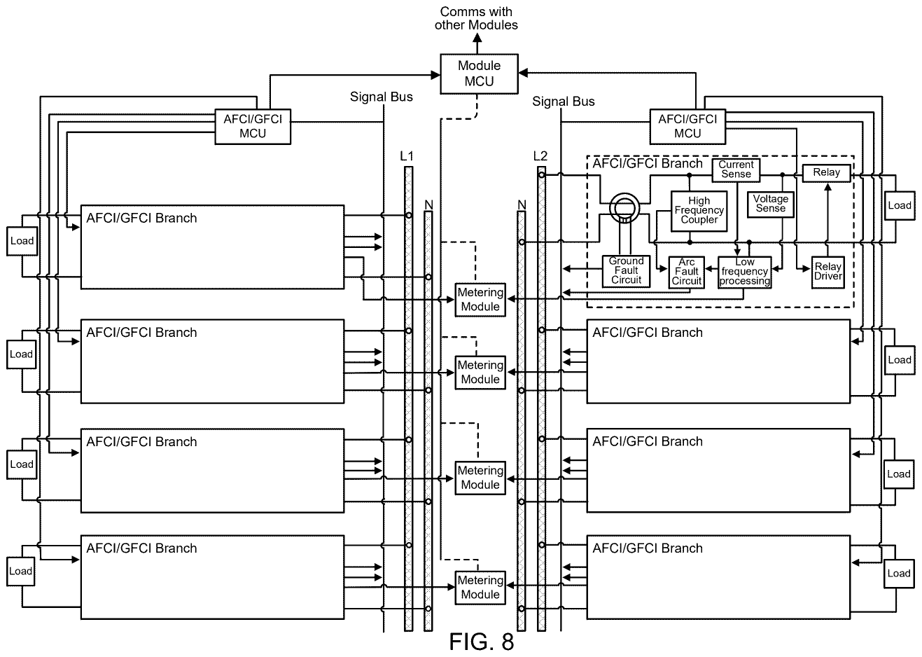

Decentralized. FIG. 8 shows the module level AFCI/GFCI functionality per branch. FIG. 8 shows sensors for each branch, and one processor (MCU) per four branches connecting to a Module MCU. One processor per line is dedicated to process the arc fault and ground fault signals and actuate the load relays independently. The signals that can be of high frequency, are transmitted to the corresponding MCU in a signal bus (one per line). Separately the Module MCU processes power, voltage and current metering. The Module MCU communicates with the line AFCI MCUs to receive relay status and fault detection. Furthermore, the Module MCU communicates with other modules in the panel and performs the user interfacing functions as test/reset buttons.

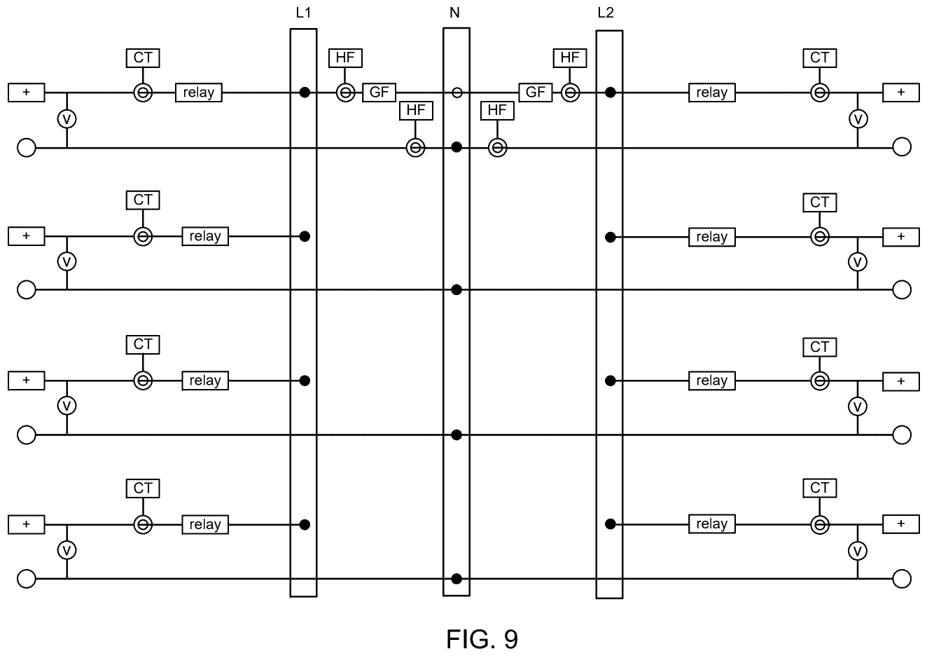

Centralized. FIG. 9 shows a modular AFCI/GFCI architecture for the 8 branches of a module communicating to a central MCU of the module that can communicate with the rest of the panel. Here there is a central location for the AFCI signal (HF) and the GFCI signal (GF) determining the fault with the current sensors (marked CT) only on the branch. This may be more cost effective, but it only determines a fault for the whole module. One can consider many different implementations of the functions. The AFCI MCU can be centralized as shown per L1/L2, it can also be part of 1, 2, 4 modules.

FIG. 9 shows the sensing part of the implementation without the communications and MCU. High frequency sensing is done centrally by an AF pickup between L1/N and L2/N. This can be done either on the line or on the neutral side.

### IV. Modular Smart Panel Chassis

This section provides more information about the smart panel chassis that holds the Branch Modules. Additional information is provided in U.S. application Ser. No. 18/586,365, which is incorporated by reference herein. The system includes control loops for the individual circuits of the microgrid. A typical control loop includes a sensor(s), processing and an actuator(s). The system may be distributed, meaning that these components may be positioned at different physical locations throughout the distribution network. For example, sensors may be positioned at outlets or electrical fixtures, instead of or in addition to being positioned at the panel. Processing for the control loops may be implemented by shared processors rather than dedicated processors, thus reducing the overall cost of the system. Actuators may also be positioned at different points within the distribution network.

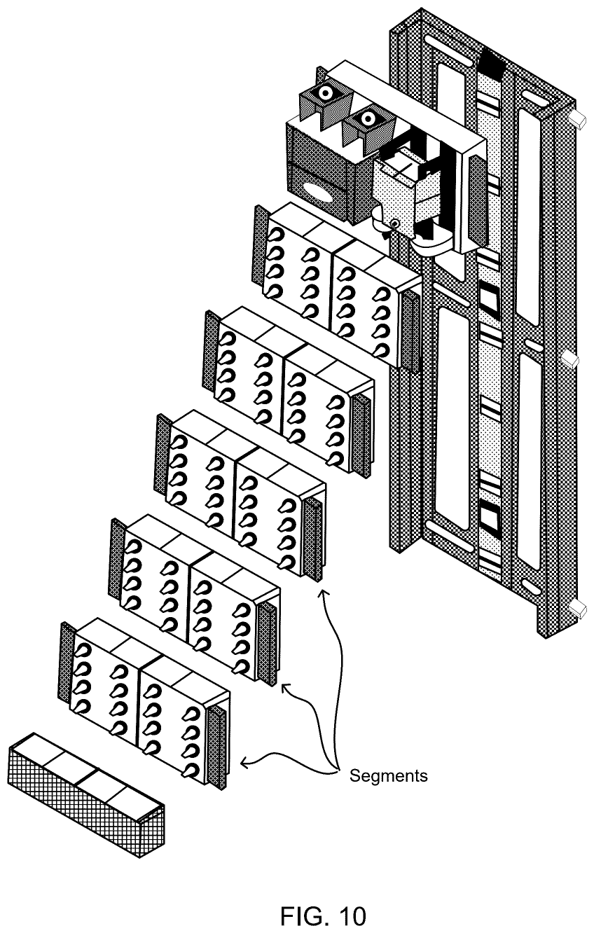

Different site topologies may require different electrical panels. To ensure that installers have panels that are the right size for the job, the system described herein features an electrical panel with a modular chassis which enables panels of arbitrary size. To accomplish this, the system panel splits the breaker terminal section of the backplate into (e.g., 4″ tall) segments which can be recombined within the chassis as needed. An example system panel with segments is shown in FIG. 10.

This section describes the hardware architecture of the system, including basic patterns such as direct MCU-to-MCU communications and the modular chassis. One aspect of the system described herein is modularity. Control modules may be distributed throughout the site and still work together. A single site controller/gateway may serve as an integrated energy management controller which administers all of the devices which generate, store, use, and/or control electricity in the home.

### A. System

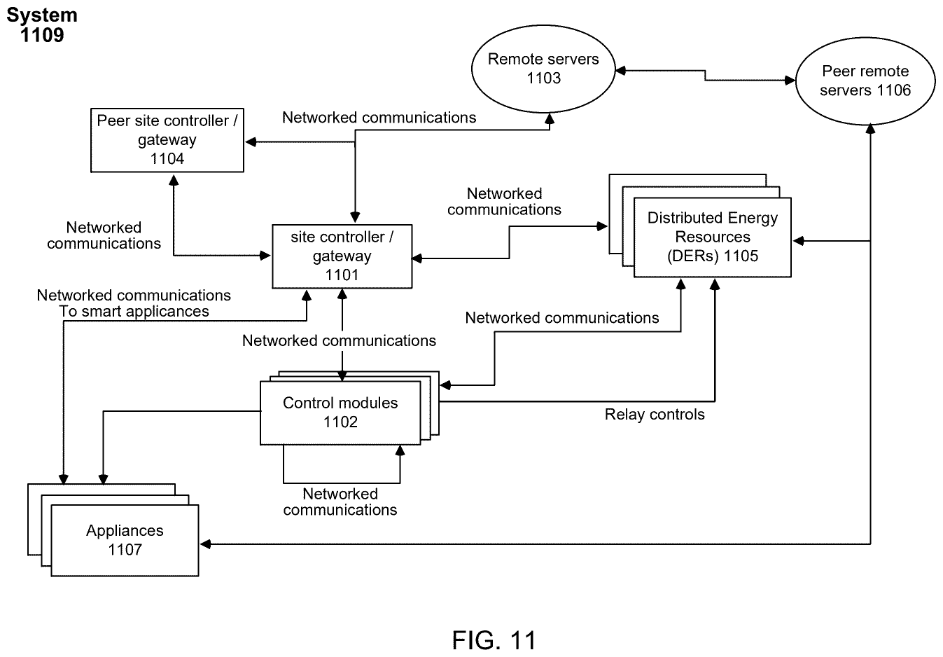

FIG. 11 shows an example system (e.g., the site controller/gateway communicates with the other components, such as the peer site controller/gateway and the appliances). The system 1109 in FIG. 11 contains the following devices and components.

Site controller/gateway 1101: E.g., a single or multi-board computer with a computing platform, such as a microprocessor or microcontroller, integrated circuits for communications protocols such as Ethernet, WiFi, Bluetooth, Cellular communications, etc., and the associated connectors and antennas.

Control module 1102: As described below.

Networked communications: One of many network communications protocols.

Appliance 1107: Any electrical load in a home, such as an electric clothes dryer, but also including unidirectional AC electric vehicle service equipment (EVSEs).

Distributed Energy Resource (DER) 1105: A Distributed Energy Resource, including distributed generation or storage, such as solar inverters, batteries (e.g., backup batteries), or bidirectional EVSEs.

Peer site controller/gateway 1104: Another site controller. This may be a peer in the sense of controlling an adjacent site—for example, multiple sites might cooperate to protect an upstream asset such as a distribution transformer—or it may be an upstream controller, for example a “site” controller assigned to monitor a substation.

Remote server 1103: e.g. the backend (running on data centers in a public cloud).

Peer remote servers 1106: In some cases the site controller/gateway may interface with third-party devices (appliances and/or DERs) which do not implement locally available APIs. In those cases, the site controller/gateway may dispatch requests to those devices via the cloud, e.g. by submitting a request to the backend over MQTT which then results in a RESTful HTTP call to the third party's servers which then relays the request back over the Internet to the third-party device.

One implementation of this system uses three communication modes performing dedicated functions. These networks are an external communications network, a local communications network, and an internal communications network. External communications refers to communications to systems and services external to the system, which usually is also external to the site. The local communications network may be designed to overcome challenges of the external communications channels. The local communications network may be a closed network between panels that are located at one site (inter-panel communications). The internal communications network is the network between modules within one product (e.g. intra-panel communications). This can be implemented using a low-cost, ubiquitous communications bus such as CAN. In one approach, this is implemented using a common “low voltage spine.” As more modules are added to the panel, the new modules are connected to the spine.

Discovery is the process by which a module knows it is connected to a Panel Control Module (described below) and vice versa. The Panel Control Module(s) coordinates actions of the control modules. Enumeration is the process by which each control module connected to the Panel Control Module is assigned a specific communication address for future messages. Discovery and enumeration can happen during the initial installation of the product, during upgrades and expansions of the products, or during replacement of a module within a product. Other types of module registration may be used.

### B. Control Module

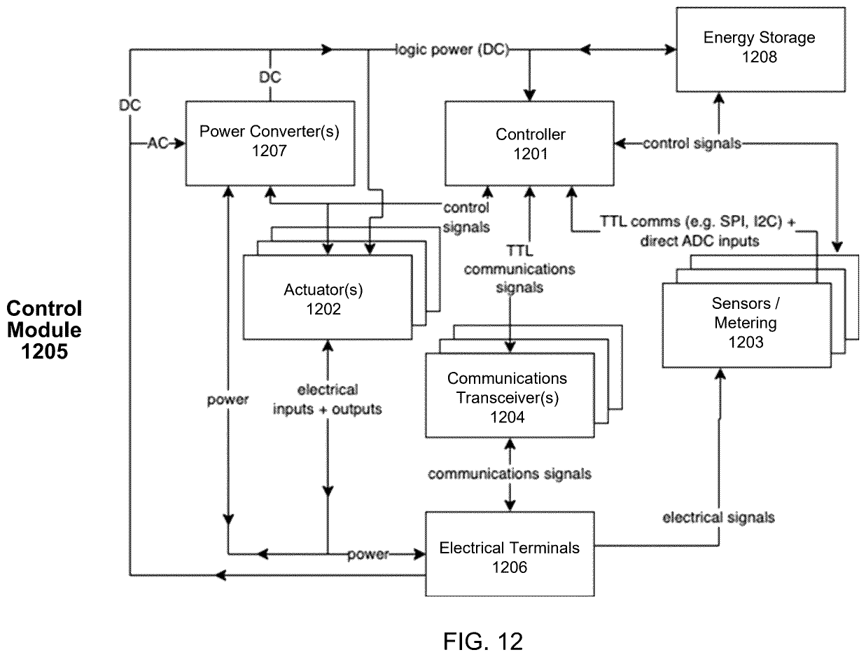

A Control Module is an individual device capable of providing a function such as metering, relay control, or power conversion. Control modules may have multiple functions (e.g. metering and relay control). In some cases, control modules may have only one of sensing, actuation, or conversion capabilities. See an example module in FIG. 12.

Control modules include AC chassis modules (i.e., housed in the electrical panel), such as Branch Module, Panel Control Module, and MID/Main Breaker Module. They may also include AC/DC chassis modules, and distributed small modules such as smart outlets, remote meters, and smart junction boxes.

The Control module 1205 in FIG. 12 shows the following hardware components, but not all components will be in every control module.

Controller 1201: A microcontroller, DSP, or other such electronic controller. Typically one per module, although some modules may include additional microcontrollers for additional functionality or for redundancy for purposes of safety. Executes control algorithms, reads sensors, manages actuators, and implements communications to other modules and the Site Controller.

Sensor(s) 1203: e.g. a current transducer (typically as a current transformer plus burden resistor) or voltage transducer. May include additional chips or modules for sensor processing, e.g. an energy metering ASSP such as the ST Microelectronics STPM34.

Actuator(s) 1202: A physical actuator such as an electromechanical relay which allows control over the flows of electrical power in an electrical distribution system such as the wiring in a building.

Communications Transceiver(s) 1204: Transceivers for wired communications protocol and/or wireless/powerline communications means (see “Heads and Tails” below), e.g. a CAN controller +transceiver; an Ethernet MAC and PHY; or a G3-Hybrid modem with a G3-PLC line driver and/or a 900 MHz radio+antenna.

“Spine” Connector (not shown in FIG. 12): A field-wired connector which carries logic power (e.g. 12VDC), wired Head-to-Tail communications (see below), and other Head-to-Tail digital/analog signals (discussed below under Chassis).

Electrical Terminals 1206: One or more electrical terminals for series (actuation) or parallel (sensing) connection to distribution conductors. May include stabs for plug-on molded-case circuit breakers, lugs, threaded studs, solder pads, small-gauge pluggable PCB connector headers (e.g. Phoenix LPC), or other types of terminal.

Power converter(s) 1207: This could be a high-voltage to low-voltage converter for producing logic power from distribution conductors, such as a 120 VAC-to-12 VDC rectifier. It could also be a high-voltage to high-voltage power converter, e.g. an AC to DC inverter (e.g. a photovoltaic solar inverter) or an isolated DC-DC converter (e.g. a photovoltaic solar maximum-power-point tracker (MPPT)).

Energy Storage 1208: An optional capacitive reserve. Used to store energy such that the device can fail safe even if the central power supply fails suddenly.

PMIC (not shown in FIG. 12): An optional power management IC can receive logic power from the Connector(s).

### C. Chassis

The electrical panel is a set of control modules (e.g., 1205 in FIG. 12) installed into a chassis at predefined attachment points. Note that not all control modules are co-located in a chassis. The distributed EMS system will include both “standalone” control modules with their own separate enclosures for separate installation as well as “chassis” control modules intended for installation into a chassis.

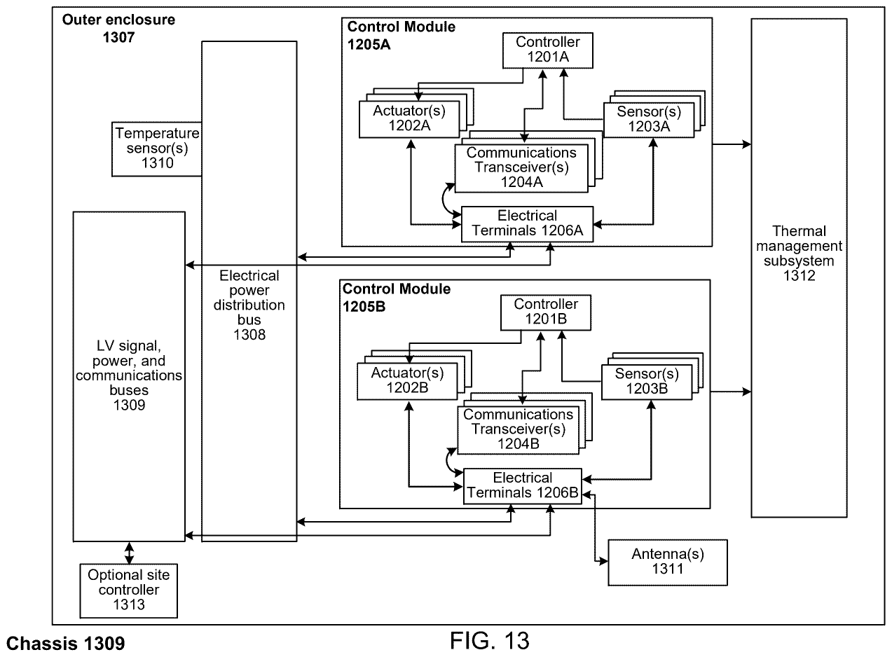

See FIG. 13 for a block diagram of a chassis 1309. A modular chassis will have some benefits to customers and installers, including the following. Among other components, the chassis 1309 includes two control modules 1205 (the reference numbers in FIG. 13 include “A” and “B” to differentiate the two modules). As described with respect to FIG. 12, each control module 1205 includes a controller 1201, actuator(s) 1202, sensor(s) 1203, communications transceiver(s) 1204, and electrical terminals 1206 (the reference numbers in FIG. 13 include “A” and “B” to differentiate the components across the two control modules)

An electrical panel, such as shown in FIG. 13, may include the following components:

Enclosure 1307: An outer enclosure responsible for protecting against dust and water ingress, providing impact resistance, and performing electromagnetic shielding as necessary. Likely made of sheet metal, although in some implementations it may be composed of plastic, optionally foil-lined for EMI.

Sub-enclosure (not shown in FIG. 13): The enclosure of a control module (e.g., 1205A) contained within the Chassis. Probably plastic. May also be foil-lined. May be protected from water and/or dust ingress using e.g. silicone gasket seals.

Electrical power distribution bus 1308: Electrical bus structure to which modules are attached by e.g. screw bolts.

LV signal, power, and communications buses 1309: The chassis also contains a low-voltage bus (different from the electrical power distribution bus), which may be implemented as a harness or a long PCBA with regularly spaced header connectors. This bus distributes logic power generated by the Logic Power Converter in one or more modules, one or more wired Head-to-Tail communications bus (e.g. CAN, possibly redundant), and one or more digital signals. It serves as an intra-panel communications network between the modules in the panel.

Antenna(s) 1311: The chassis may contain external antennas which connect to installed control modules to increase their RF transmit range.

Temperature sensor(s) 1310: The buswork in the chassis may be monitored for overtemperature, with some means of routing the signal back to one or more control modules (e.g. a temperature sensor may have a pigtail harness which connects to a pluggable PCB connector on the front of the chassis' Head Module).

Optional site controller 1313: A chassis may have a socket into which a Site Controller/Gateway may be installed. This socket may instead be located on the Head Control Module.

Thermal management subsystem 1312: A subassembly of thermal conductors, heatsinks, fins, and/or circulation or ventilation fans which serve to transfer heat from the enclosure.

### V. Examples of Chassis Modules

This section and the next section describe example implementations of different aspects of the system. This section includes examples from the electrical panel, including the customizable chassis and control modules that may be field-installed in the chassis. These may be referred to as chassis modules. The next section includes examples of standalone modules (i.e., control modules not installed in the chassis).

### A. the Electrical Panel (chassis)

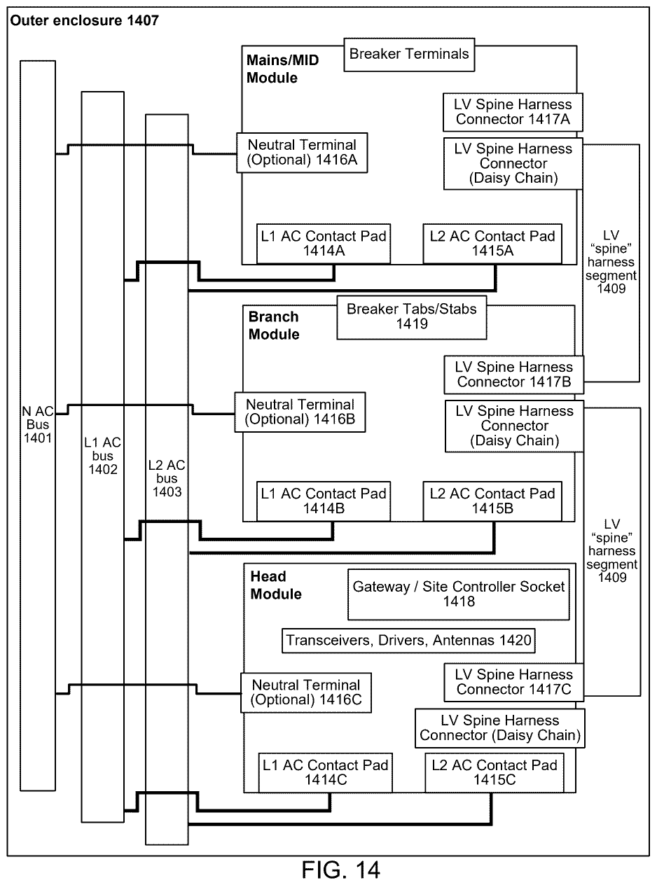

The electrical panel includes a chassis for constructing circuit breaker panelboards. It has modular construction for the benefits of customizability as described above. See FIG. 14 for an example block diagram of an electrical panel. Note that the modules are depicted in this view with externally facing features only (omitting internal components). The components shown in FIG. 14 include the following.

Outer enclosure 1407: An enclosure, some instantiations of which may be folded welded sheet metal, deep-draw stamped sheet metal, or injection molded plastic. The enclosure includes a door and a deadfront for restricting homeowner access to field-wired electrical connections. The door and/or the enclosure may include sealing features such as foamed gaskets at mating surfaces for ingress protection. The door may include latching features such as a locking hasp or an integrated smart lock. The door may be constructed of metal or plastic and may have integrated antennas and/or transparency windows for antenna projection, or may have mounting features for such. The door may also include an integrated site controller/gateway.

L1/L2 AC Bus (labeled 1402 and 1403 in FIG. 14): Busbars at the rear of the enclosure with exposed conductive surface and bolted joint fasteners and/or threaded holes for module termination.

N AC Bus 1401: A busbar or terminal block with regularly spaced screw gate apertures for “pigtail” wire connection to modules.

LV (low voltage) “spine” harness segment (labeled 1409A and 1409B in FIG. 14): A jumper harness consisting of bundled wires and factory-terminated connectors which plugs into corresponding bulkhead connectors on each module.

L1/L2 Contact Pad (labeled 1414A-C and 1415A-C in FIG. 14): An exposed surface of conducting metal such as aluminum or copper, likely as an element on a busbar, with a bolt throughhole, captive bolt or other mechanism for attachment to a chassis busbar.

Neutral Terminal (labeled 1416A-C in FIG. 14): An optional terminal for connecting a neutral wire for purposes such as ground fault detection, arc fault detection, powerline communication. May be instantiated as a contact pad, screw-gate, spring clip, pluggable connector, barrel jack, or other such styles depending on required ampacity.

LV Spine Harness Connector (labeled 1417A-C in FIG. 14): In FIG. 14, the LV (low voltage) signal and communications buses are implemented as a series of jumper harnesses which daisy chain logic power buses and digital signals/communications between modules. These connectors may be located on any installer-facing surface of the module (i.e. front and sides). Connectors may include sealing or terminal position assurance features. In some instantiations, dual parallel harnesses or a loopback from top to bottom may be used for signal redundancy.

Gateway/Site Controller Socket 1418: A socket for installing a gateway/site controller as described above. Note that in other instantiations, the gateway/site controller may be integrated into the door, attached to mounting positions on various internal or external surfaces of the chassis, or may constitute its own module.

Breaker Tabs/Stabs 1419: Electrical terminals to attach miniature circuit breakers. May include features such as tandem rejection tabs.

Transceivers, Drivers, Antennas 1420: Communications hardware as necessary to compose the “Wireless Inter-Chassis Bus” described above.

### B. Branch Module

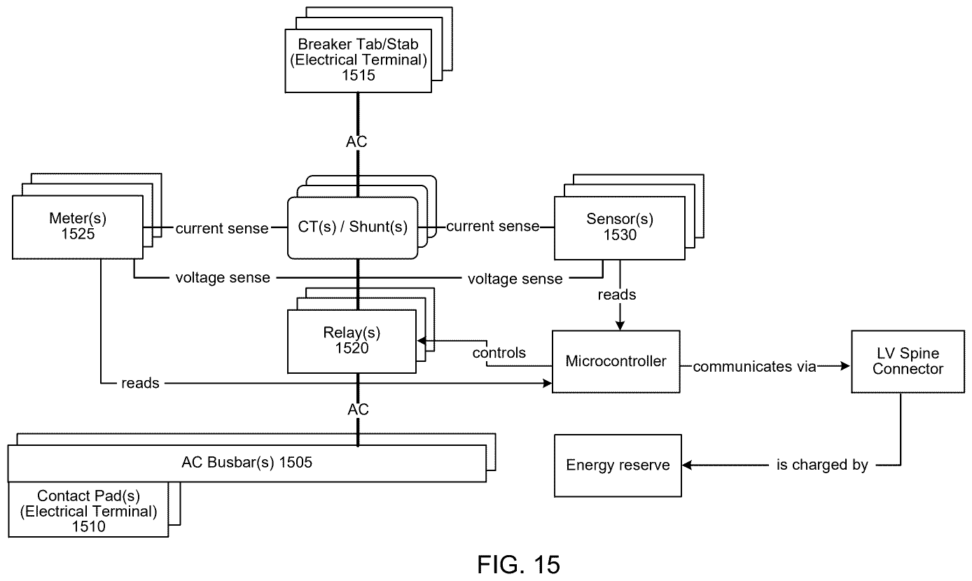

The Branch Module is a basic building block of the electrical panel. These control modules are a modularized section of panel for branch circuit breakers with integrated controls and sensing. See FIG. 15 for an example block diagram of a Branch Module. The components in FIG. 15 include the following:

AC busbar(s) 1505: Integrated electrical busbars which distribute AC power from the chassis busbars via the contact pad(s) to individual breaker tabs/stabs or conductors associated to each tab/stab.

Contact Pad(s) 1510: An exposed surface of conducting metal such as aluminum or copper, likely as an element on a busbar, with a bolt throughhole, captive bolt or other mechanism for attachment to a chassis busbar.

Breaker Tabs/Stabs 1515: Electrical terminals to attach miniature circuit breakers. May include features such as tandem rejection tabs.

Relay(s) 1520: Actuator(s) such as electromechanical relays, each of which is capable of disconnecting and reconnecting one or more of the breaker tabs/stabs to the AC busbar. May also be implemented as high-power transistors.

Meter(s) 1525: Sensor(s) that may include electronic circuits, application-specific integrated circuits (e.g. ST STPM34), microcontrollers (e.g. TI MSP430), or similar devices capable of performing electrical metering to a specific rated accuracy. In some instantiations, some or all of the breaker tabs/stabs in variants of the Branch Module may have meters omitted.

Sensor(s) 1530: Other optional electronic sensor, which may perform sensing duties on branch current and voltage concurrently/electrically parallel to the meter, and which may detect events of interest in the house, and which may communicate or send electrical signals to the microcontroller, e.g. to notify of detected events.

### C. Panel Control Module

The Panel Control Module acts as a hub for the chassis modules installed in an electrical panel. For example, it maintains a registry of the modules installed in the panel. It may provide controls to the installed modules and aggregate data from the modules. The LV spine may be used to communicate with these other modules. The Panel Control Module may also perform Head functions as described above. In some instantiations, the module includes communications transceivers such as e.g. RS485 or CAN for communication to third party devices such as solar inverters, batteries, generators. In some instantiations, the module includes low voltage relays and switches, e.g. to interrupt the 24 VAC control line to HVAC systems. In some instantiations, the module includes meters or sensors which accept electrical signals from field wired connectors, e.g. a pluggable connector for externally placed CTs. In some instantiations, meters may measure voltage from the module's contact pads and current from externally placed coverage targets. In others, voltage may be externally provided or selectable between the two by means of e.g. installer-accessible switches or field installable jumpers. Being able to read and send dry contact states, communicate on CAN, and do auxiliary metering directly from the panel itself make the panel well-suited to integration with other third-party equipment.

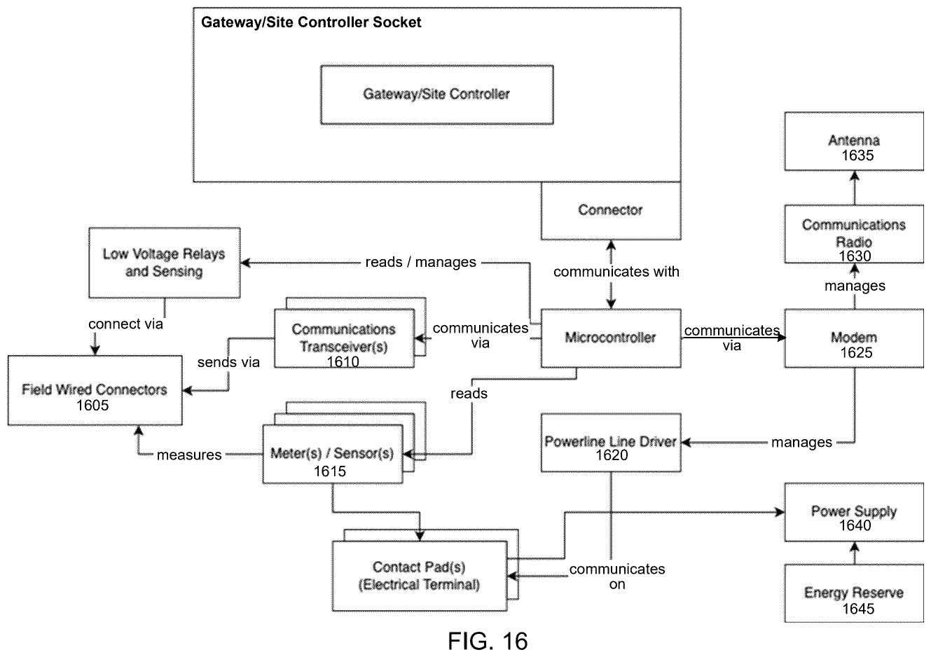

See FIG. 16, which includes the following components:

Field Wired Connectors 1605: One or more electrical terminals for field wiring, including screw gate connectors, spring clip, or pluggable connectors.

Communication transceiver(s) 1610: Optionally, transceivers used for communication with other devices such as EVSEs, solar inverters, batteries, appliances, or external sensors. Example instantiations include RS485 transceivers (e.g. for Sunspec Modbus to solar inverters) and CAN transceivers (e.g. for communications to storage batteries).

Meter(s)/Sensor(s) 1615: Electrical meters and other electronic sensors which measure AC voltage at the contact pads.

Powerline Line Driver 1620, Modem 1625, Communications Radio 1630, Antenna 1635: Hardware for supporting Head functionality, i.e. wireless/powerline communications. In FIG. 16, a modem is used which manages both an AC line driver for powerline communications (e.g. HomePlug Green PHY or similar), and a radio (e.g. Zigbee). In other instantiations one or the other may be used and/or the microcontroller may manage them directly rather than being mediated by a modem.

Power Supply 1640, Energy Reserve 1645: A power supply capable of generating DC logic power from AC via the contact pads and distributing it to the LV spine, and a source of energy (battery, capacitor, or similar) either before the power supply (i.e. storing rectified AC) or after the power supply (i.e. storing logic-level DC), which can be used to continue providing power to the module and (in some instantiations) other modules on the LV spine. The power supply and energy reserve are not depicted as wired to anything and should be understood to be capable of powering all of the electronic/electrical components in the module. In some instantiations, certain components may be not powered or selectively powered to allow downsizing of the energy reserve.

Although the detailed description contains many specifics, these should not be construed as limiting the scope of the invention but merely as illustrating different examples. It should be appreciated that the scope of the disclosure includes other embodiments not discussed in detail above. Various other modifications, changes and variations which will be apparent to those skilled in the art may be made in the arrangement, operation and details of the method and apparatus disclosed herein without departing from the spirit and scope as defined in the appended claims. Therefore, the scope of the invention should be determined by the appended claims and their legal equivalents.

What is claimed is:

1. An electrical panel for managing a distribution of electrical power throughout a microgrid at a site, the electrical panel comprising:
a chassis comprising:
a bus structure that receives electrical power, and
a plurality of predefined attachment points for installation of field-replaceable control modules;
a field-replaceable branch module installed at the attachment points with electrical connection to the bus structure, the branch module distributing electrical power from the bus structure to multiple branch circuits of the microgrid and providing AFCI and/or GFCI protection for the branch circuits;
a field-replaceable panel control module installed at one of the attachment points with electrical connection to the bus structure, wherein the panel control module maintains a registry that includes the installed branch module; and
an intra-panel communications network, over which the panel control module communicates data and control with the branch module.

2. The electrical panel of claim 1 wherein the electrical panel receives over-the-air software updates of the AFCI and/or GFCI protection via the intra-panel communications network.

3. The electrical panel of claim 1 comprising: a plurality of field-replaceable branch modules installed at the attachment points with electrical connection to the bus structure, each branch module distributing electrical power from the bus structure to multiple branch circuits of the microgrid and providing AFCI and/or GFCI protection for the branch circuits.

4. The electrical panel of claim 1 further comprising: a visual indicator on the electrical panel configured to indicate a state of the AFCI and/or GFCI protection for the branch circuits.

5. A system for managing a distribution of electrical power throughout a microgrid at a site, the system comprising:
a plurality of field-installable control modules that provide sensor, processor and/or actuator capabilities for the microgrid;
a microgrid control module that maintains a registry of the installed control modules;
an intra-site communications network, over which the microgrid control module communicates data and control with the control modules;
a gateway connected to the microgrid control module, the gateway connecting to an external communications network; and
an electrical panel with a plurality of predefined attachment points at which at least one of the control modules is installed, wherein the microgrid control module is a panel control module installed in the electrical panel, and the at least one installed control module includes a field-replaceable branch module that distributes electrical power from the bus structure to multiple branch circuits of the microgrid and provides AFCI and/or GFCI protection for the branch circuits.

6. The system of claim 5 wherein the system tracks a history of AFCI and/or GFCI faults.

7. The system of claim 5 wherein the system additionally institutes a lockout upon detection of abnormal voltage.

8. The system of claim 5 wherein the system additionally institutes a lockout upon detection of AFCI and/or GFCI faults on multiple branch circuits.

9. The system of claim 5 wherein the system additionally correlates AFCI and/or GFCI faults on branch circuits with load events on the branch circuits.

10. The system of claim 5 wherein the GFCI protection includes a GFCI warning at electricity levels below a GFCI fault level.

11. The system of claim 5 further comprising: an app that indicates a state of the AFCI and/or GFCI protection for the branch circuits.

12. The system of claim 11 wherein the app further provides user control over the AFCI and/or GFCI protection for the branch circuits.

13. A field-replaceable branch module installable at attachment points of a chassis of an electrical panel, the branch module distributing electrical power from a bus structure of the electrical panel to multiple branch circuits of a microgrid and providing AFCI and/or GFCI protection for the branch circuits.

14. The field-replaceable branch module of claim 13 wherein the branch module provides separate AFCI protection for each individual branch circuit.

15. The field-replaceable branch module of claim 13 wherein the branch module provides centralized AFCI protection for all of the branch circuits.

16. The field-replaceable branch module of claim 13 wherein the branch module provides separate GFCI protection for each individual branch circuit.

17. The field-replaceable branch module of claim 13 wherein the branch module provides centralized GFCI protection for all of the branch circuits.

18. The field-replaceable branch module of claim 13 wherein the branch module provides AFCI and/or GFCI protection for dipole breakers and/or for tandem breakers.

19. The field-replaceable branch module of claim 13 further comprising:
current sensors that sense the electricity flowing through the branch circuits;
actuators that control the electricity flowing through the branch circuits; and
a processor that controls the actuators based on the electricity flow sensed by the current sensors in accordance with AFCI and/or GFCI specifications.

20. The field-replaceable branch module of claim 13 further comprising:
current sensors that sense the electricity flowing through the branch circuits;
actuators that control the electricity flowing through the branch circuits; and
an interface to an intra-panel communications network, over which the branch module communicates with a processor external to the branch module, wherein the processor controls the actuators based on the electricity flow sensed by the current sensors in accordance with AFCI and/or GFCI specifications.
